(19) United States
(12) Patent Application Publication
(10) Pub. No.: US 2012/0068218 A1
(43) Pub. Date: Mar. 22, 2012

(54) THERMALLY EFFICIENT PACKAGING FOR A PHOTONIC DEVICE

(75) Inventors: Hung-Pin Chang, Taipei (TW); Yung-Chi Lin, Su-Lin City (TW); Chia-Lin Yu, Singang Township (TW); Jui-Ping Hung, Hsinchu (TW); Chien Ling Hwang, Hsin-Chu (TW); Chen-Hua Yu, Hsin-Chu (TW)

(73) Assignee: TAIWAN SEMICONDUCTOR MANUFACTURING COMPANY, LTD., Hsin-Chu (TW)

(21) Appl. No.: 12/884,570

(22) Filed: Sep. 17, 2010

(51) Int. Cl. H01L 33/62; H01L 21/50

(52) U.S. Cl. 257/99; 438/26; 257/E33.056; 257/E21.499; 257/E33.066

(57) ABSTRACT

The present disclosure provides a method of packaging for a photonic device, such as a light-emitting diode device. The packaging includes an insulating structure. The packaging includes first and second conductive structures that each extend through the insulating structure. A substantial area of a bottom surface of the light-emitting diode device is in direct contact with a top surface of the first conductive structure. A top surface of the light-emitting diode device is bonded to the second conductive structure through a bonding wire.

### TECHNICAL FIELD

The present disclosure relates generally to packaging, and more particularly, to packaging of a light-emitting diode (LED) device.

### BACKGROUND

The semiconductor integrated circuit (IC) industry has experienced rapid growth. Technological advances in IC materials and design have produced various types of ICs that serve different purposes. One type of these ICs is photonic devices, such as LED devices. Traditional methods of packaging of these LED devices may suffer from problems such as inefficient thermal dissipation, poor reliability, and costly fabrication.

Therefore, while existing methods of packaging the LED devices have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method of packaging a photonic device according to various aspects of the present disclosure; and

FIGS. 2-9 are diagrammatic cross-sectional side views of packaging for a photonic device at various stages according to an embodiment of the method of FIG. 1.

### SUMMARY

One of the broader forms of the present disclosure involves an apparatus that includes a packaging for a light-emitting diode (LED) device. The packaging includes: an insulating structure; and first and second conductive structures that each extend through the insulating structure; wherein: a substantial area of a bottom surface of the LED device comes into contact with a top surface of the first conductive structure; and a top surface of the LED device is bonded to the second conductive structure through a bonding wire.

Another one of the broader forms of the present disclosure involves an apparatus that includes a packaging structure for a photonic device. The packaging structure includes: an insulating structure; and a thermally conductive structure partially disposed in the insulating structure; wherein a substantial portion of a surface of the photonic device is in direct contact with the thermally conductive structure.

Still another one of the broader forms of the present disclosure involves a method of packaging a light-emitting diode (LED) device. The method includes: forming an insulating structure; forming a thermally conductive structure partially in the insulating structure; providing the LED device, the LED device having a top surface and a bottom surface; and bonding the LED device to the thermally conductive structure, the bonding being carried out in a manner so that a substantial portion of one of the top and bottom surfaces of the LED device is in direct contact with the thermally conductive structure.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

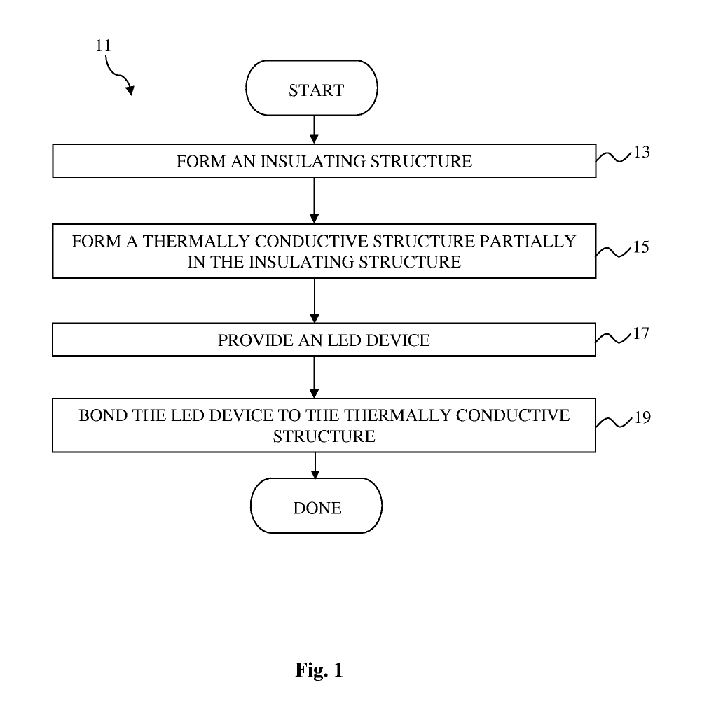

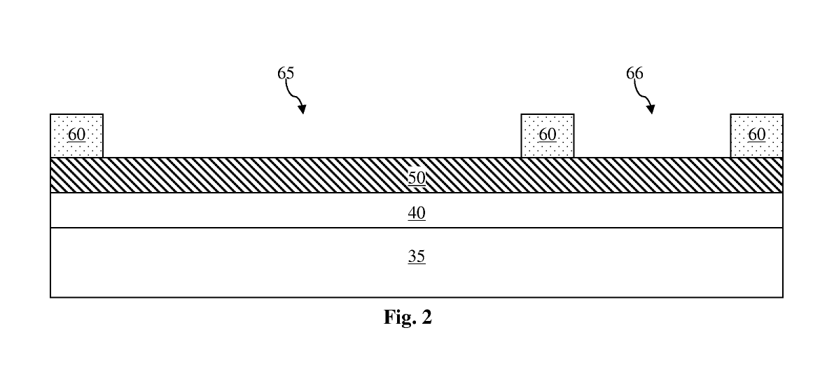

Illustrated in FIG. 1 is a flowchart of a method 11 for packaging a photonic device in accordance with various aspects of the present disclosure. FIGS. 2-9 are diagrammatic fragmentary cross-sectional side views of the packaging during various stages in accordance with an embodiment of the method 11 in FIG. 1. The photonic device may be a light-emitting diode (LED) device. It is understood that FIGS. 2-9 have been simplified for a better understanding of the inventive concepts of the present disclosure. Accordingly, it should be noted that additional processes may be provided before, during, and after the method 11 of FIG. 1, and that some other processes may only be briefly described herein.

Referring to FIG. 1, the method 11 begins with block 13 in which an insulating structure is provided. The method 11 continues with block 15 in which a thermally conductive structure is partially formed in the insulating structure. The method 11 continues with block 17 in which a photonic device having a top surface and a bottom surface is provided. The method 11 continues with block 19 in which the photonic device is bonded to the thermally conductive structure. The bonding is performed in a manner so that a substantial portion of one of the top surface and the bottom surface of the photonic device is in direct contact with the thermally conductive structure.

Referring now to FIG. 2, a carrier substrate 35 is provided. The carrier substrate 35 may include a transparent material. The carrier substrate 35 is a temporary substrate and will be removed in a later process. A sacrificial layer 40 is then formed over the carrier substrate 35. The sacrificial layer 40 may include a glue material or an adhesive material. The sacrificial layer 40 may include more than one layer.

A conductive seed layer 50 is then formed over the sacrificial layer 40. The conductive seed layer 50 has good thermal and electrical conductivity. The conductive seed layer 50 includes a metal material, such as titanium (Ti), tantalum (Ta), copper (Cu), aluminum (Al), nickel (Ni), or another suitable material. The conductive seed layer 50 may be formed by a physical vapor deposition (PVD) process known in the art. The conductive seed layer 50 may also be referred to as a bottom conductive seed layer.

A patterned insulating layer 60 is formed over the conductive seed layer 50. The patterned insulating layer 60 has openings 65 and 66. In the present embodiment, the patterned insulating layer 60 includes a material that can be directly patterned. For example, the patterned insulating layer 60 may include a photo-sensitive material such as photoresist, a polymer material, or an epoxy material. The formation of the patterned insulating layer 60 in the present embodiment does not require an etching process to form the openings 65 and 66. Rather, a photolithography process is used to directly transfer a desired image pattern from a photomask (not illustrated) to the photoresist to form the patterned insulating layer 60. The patterned insulating layer 60 may also be referred to as a bottom pad mold.

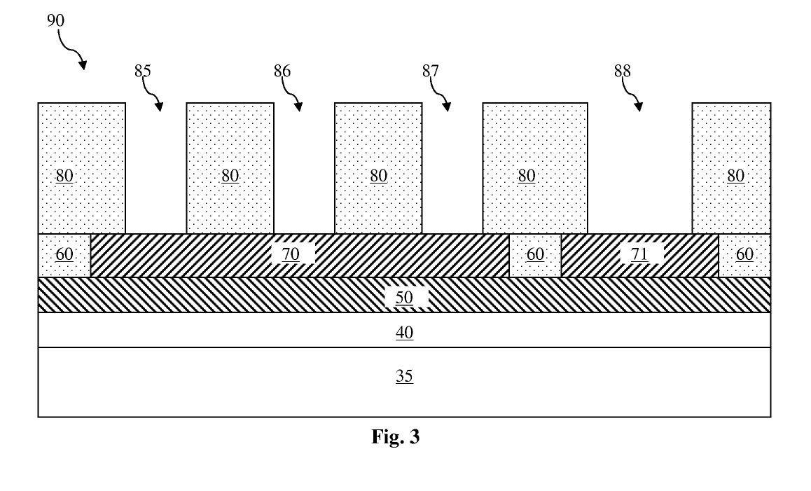

Referring to FIG. 3, conductive contact pads 70 and 71 are formed to fill the openings 65 and 66 (shown in FIG. 2), respectively. The conductive contact pads 70 and 71 have good thermal and electrical conductivity. The conductive contact pads 70 and 71 include a metal material, such as Cu, Ni, Al, or another suitable conductive material. The conductive pads 70 and 71 are formed by a plating process known in the art. The conductive seed layer 50 serves as the seed layer for the plating process. The plating process forms the conductive pads 70 and 71 in a manner so that the conductive pads 70 and 71 are substantially co-planar with the patterned insulating layer 60. In other words, the plating process can be tuned so that the conductive pads 70 and 71 would neither over-fill nor under-fill the openings 65 and 66 (shown in FIG. 2).

Thereafter, a patterned insulating layer 80 is formed over the conductive pads 70 and 71 and the patterned insulating layer 60. The patterned insulating layer 80 includes openings 85, 86, 87, and 88. Similar to the patterned insulating layer 60, the patterned insulating layer 80 in the present embodiment includes a material that can be directly patterned, for example a photoresist material. As such, the formation of the patterned insulating layer 80 in the present embodiment employs no etching process to form the openings 85-88. Rather, a photolithography process is used to directly transfer a desired pattern from a photomask (not illustrated) to the photoresist to form the patterned insulating layer 80. The patterned insulating layer 80 may also be referred to as an interposer mold, since the openings 85-88 are interposed by (or interleaved with) portions of the patterned insulating layer 80. The patterned insulating layers 60 and 80 may be collectively viewed as an insulating structure 90.

It is understood that the openings 85-88 formed here are merely examples, and that fewer openings or additional openings may be formed in the patterned insulating layer 80 in other embodiments.

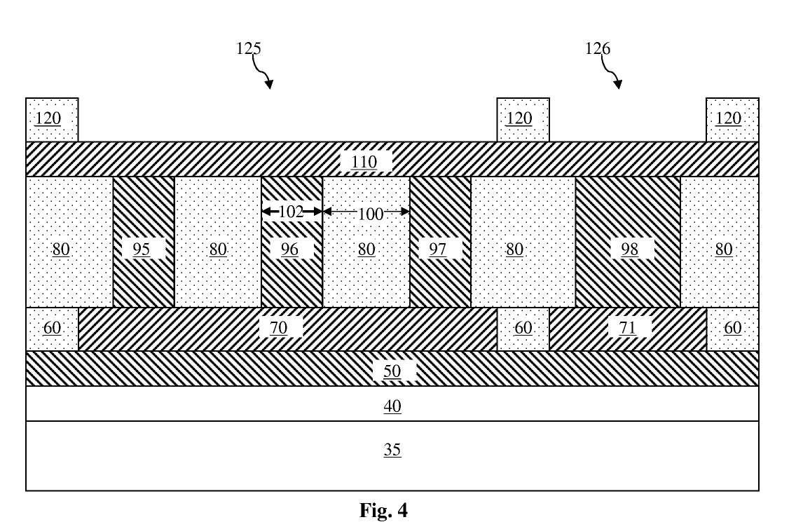

Referring now to FIG. 4, conductive features (also referred to as conductive columns) 95, 96, 97, and 98 are formed to fill the openings 85, 86, 87, and 88 (shown in FIG. 3), respectively. The conductive features 95-98 have good thermal and electrical conductivity. The conductive features 95-98 include a metal material, such as Cu, Ni, Al, or another suitable conductive material. The conductive features 95-98 are formed by a plating process known in the art. The plating process forms the conductive features 95-98 in a manner so that the conductive features 95-98 may be substantially co-planar with the patterned insulating layer 80. In other words, the plating process can be tuned so that the conductive features 95-98 would neither over-fill nor under-fill their respective openings 85-88 (shown in FIG. 3).

The portions of the patterned insulating layer 80 interleaving with the conductive features 95-97 each have a width (or a lateral dimension) 100, and the conductive features 95-97 each have a width (or lateral dimension) 102. The widths 100 and 102 are measured in a horizontal direction. In an embodiment, a ratio between the value of the width 100 and the value of the width 102 is in a range from approximately 0.5:1 to approximately 5:1, for example approximately 1:1.

It is understood that in some embodiments, the values of the widths of the conductive features 95-97 may not all be equal to one another. For example, the conductive feature 95 may have one width value, and the conductive feature 96 and 97 may have other width values that are different from the width values of the conductive feature 95. Similarly, the width values of the patterned insulating layers 80 may not be equal to one another. The specific width values and the ratios between the values of the widths 100 and 102 may be tuned/adjusted depending on design and manufacturing needs and requirements. It is also understood that in some alternative embodiments, the openings 85-87 (FIG. 3) may be merged into one opening. Thus, the conductive features 95-97 would not be formed separately, but would be formed as a single conductive feature in those alternative embodiments.

A conductive seed layer 110 is then formed over the patterned insulating layer 80 and the conductive features 95-98. The conductive seed layer 110 has good thermal and electrical conductivity. The conductive seed layer 110 includes a metal material, such as Ti, Ta, Cu, Al, Ni, or another suitable material. The conductive seed layer 110 may be formed by a PVD process known in the art. The conductive seed layer 110 may also be referred to as a top conductive seed layer.

Thereafter, a patterned insulating layer 120 is formed over the conductive seed layer 110. The patterned insulating layer 120 includes openings 125 and 126. Similar to the insulating layers 60 and 80, the patterned insulating layer 120 includes a material that can be directly patterned, for example a photoresist material. Thus, similar to the insulating layers 60 and 80, the insulating layer 120 is formed by a photolithography process rather than an etching process. The patterned insulating layer 120 may also be referred to as a top pad mold.

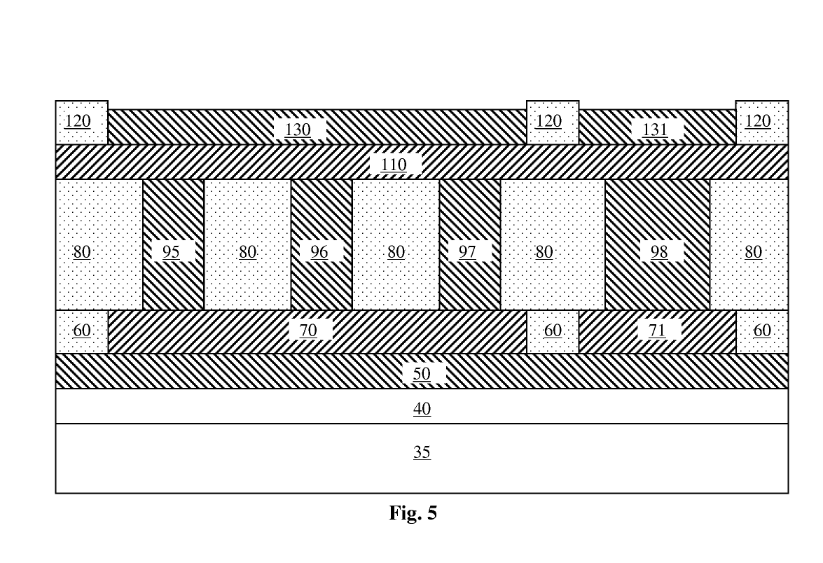

Referring now to FIG. 5, conductive contact pads 130 and 131 are formed to at least partially fill the openings 125 and 126 (shown in FIG. 4), respectively. The conductive contact pads 130 and 131 have good thermal and electrical conductivity. The conductive contact pads 130 and 131 include a metal material, such as Cu, Ni, Al, or another suitable conductive material. The conductive pads 130 and 131 are formed by a plating process known in the art. The conductive seed layer 110 serves as the seed layer for the plating process.

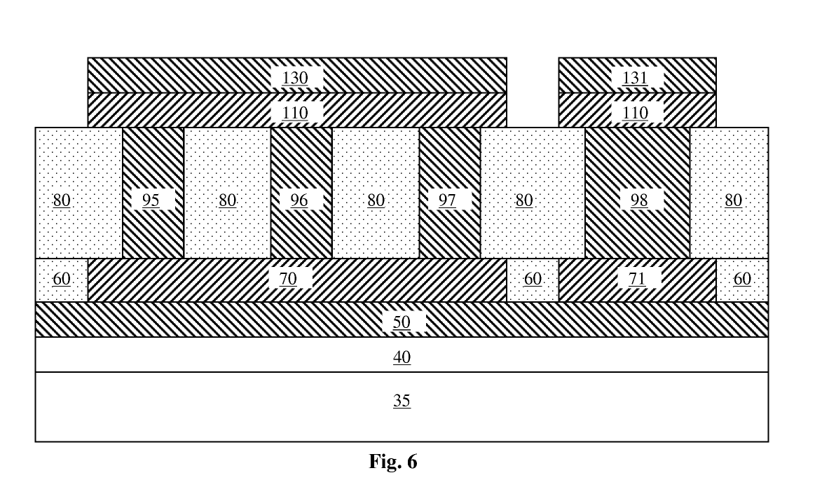

Referring now to FIG. 6, the patterned insulating layer 120 (shown in FIG. 5) is removed, for example using a stripping or ashing process known in the art. Exposed surfaces of the conductive seed layer 110 and the conductive contact pads 130 and 131 are then cleaned. Thereafter, portions of the conductive seed layer 110 that are unprotected by the conductive contact pads 130 and 131 are removed, for example using a wet etching or a dry etching process known in the art.

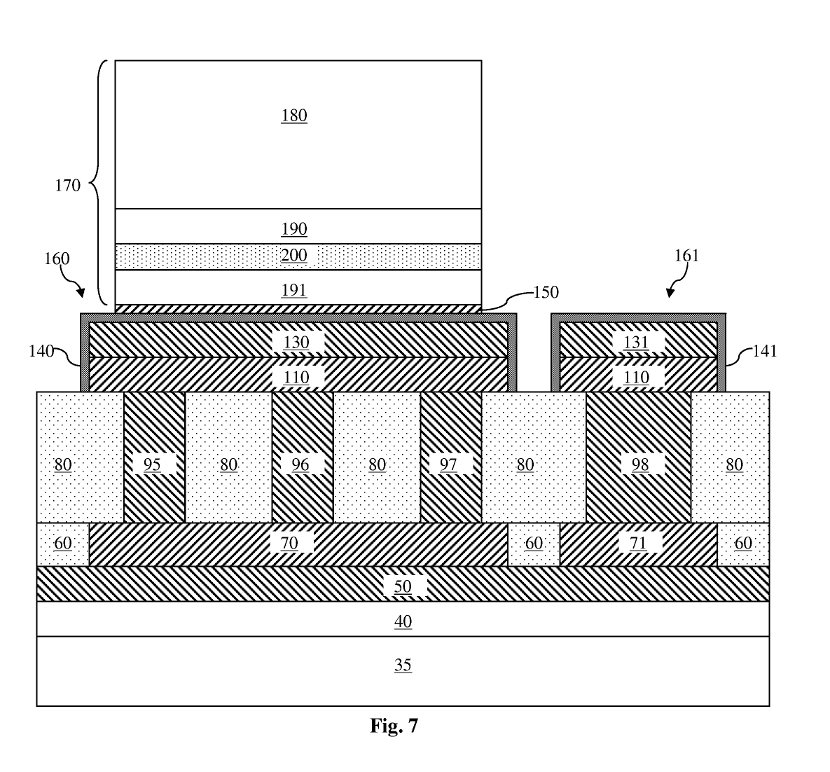

Referring now to FIG. 7, barrier layers 140 and 141 are optionally formed on exposed surfaces of the conductive contact pads 130 and 131 and the contact seed layer 110 therebelow, respectively. The barrier layers 140 and 141 may include Ni, Electroless Nickel/Immersion Gold (ENIG), or Electroless Nickel Electroless Palladium Immersion Gold (ENEPIG). The barrier layers 140 and 141 help protect the conductive seed layer 110 and the conductive contact pads 130 and 131 from corrosion and undesired oxidation.

A bond joint 150 is then formed on the barrier layer 140 (and on the conductive contact pad 130 if the barrier layer 140 is not formed). The bond joint 150 includes a material suitable for soldering, such as lead (Pb). Since the barrier layer 140 and the bond joint 150 each include a conductive material such as metal (similar to the conductive contact pad 130), they may be viewed as a part of, or an extension of the conductive contact pad 130. Thus, a thermally conductive structure 160 is formed collectively by the conductive contact pads 70 and 130, the conductive features 95-97, the conductive seed layer 110, the optional barrier layers 140, and the bond joint 150. Also, a thermally conductive structure 161 is formed collectively by the conductive contact pads 71 and 131, the conductive feature 98, the conductive seed layer 110, and the optional barrier layers 141. It is also understood that the thermally conductive structures 160-161 may be collectively viewed as a single thermally conductive structure.

A photonic device 170 is then bonded to the conductive contact pad 130 through the bond joint 150. The photonic device 170 is a light-emitting diode (LED) device in the present embodiment, but may be other suitable photonic devices in alternative embodiments. The photonic device 170 includes a substrate 180, two oppositely doped layers 190 and 191 that are formed over the substrate 180, and a multiple-quantum well (MQW) layer 200 that is disposed in between the doped layers 190 and 191.

The substrate 180 includes a material that is suitable for growing a light-emitting material. Thus, the substrate 180 may also be referred to as a growth substrate or a growth wafer. In one embodiment, the substrate 180 includes a sapphire material. In other embodiments, the substrate 180 may include silicon carbide, silicon, or another suitable material for growing the light-emitting material.

The doped layer 190 includes a p-type material, and the doped layer 191 includes an n-type material. In an embodiment, the doped layer 190 includes a gallium nitride (GaN) material doped with a p-type dopant such as boron (B), and the doped layer 191 includes a gallium nitride material doped with an n-type dopant such as arsenic (As) or phosphorous (P). In an alternative embodiment, the doped layer 190 may include an n-type material, and the doped layer 191 may include a p-type material.

The MQW layer 200 includes alternating (or periodic) layers of gallium nitride and indium gallium nitride (InGaN). For example, in one embodiment, the MQW layer 200 includes ten layers of gallium nitride and ten layers of indium gallium nitride, where an indium gallium nitride layer is formed on a gallium nitride layer, and another gallium nitride layer is formed on the indium gallium nitride layer, so on and so forth.

The doped layers 190 and 191 and the MQW layer 200 are all formed by an epitaxial growth process known in the art. In the epitaxial growth process, the substrate 180 acts as a seed crystal, and the layers 190-191 and 200 take on a lattice structure and an orientation that are substantially identical to those of the substrate 180. After the completion of the epitaxial growth process, a P/N junction (or a P/N diode) is formed by the disposition of the MQW layer 200 between the doped layers 190 and 191. When an electrical voltage (or electrical charge) is applied to the doped layers 190 and 191, electrical current flows through the photonic device 170, and the MQW layer 200 emits radiation such as observable light. The color of the light emitted by the MQW layer 200 corresponds to the wavelength of the light, which may be tuned by varying the composition and structure of the materials that make up the MQW layer 200.

In the embodiment shown in FIG. 7, the photonic device 170 is “flipped” upside down such that a substantial area or surface of the doped layer 191 is in direct physical contact with the bond joint 150. In an embodiment, the entire bottom surface of the doped layer 191 is in direct physical contact with the bond joint 130. As mentioned above, since the bond joint 150 may be viewed as a part of, or an extension of the conductive contact pad 130, it may be said that a substantial portion of the bottom surface of the photonic device 170 comes into direct physical contact with the conductive contact pad 130.

It is understood that other photonic devices (not illustrated) similar to the photonic device 170 may be formed on the substrate 180. These photonic devices may be individually separated from one another before the photonic device 170 is bonded to the conductive pad 130 through the bond joint 150. The separation of these photonic devices may be achieved through one or more processes such as dry etching or slicing with a laser beam or a saw blade. It is also understood that the bond joint 150 may be formed on the photonic device 170 instead of being formed on the barrier layer 140, for example in the form of a solder ball or solder bump.

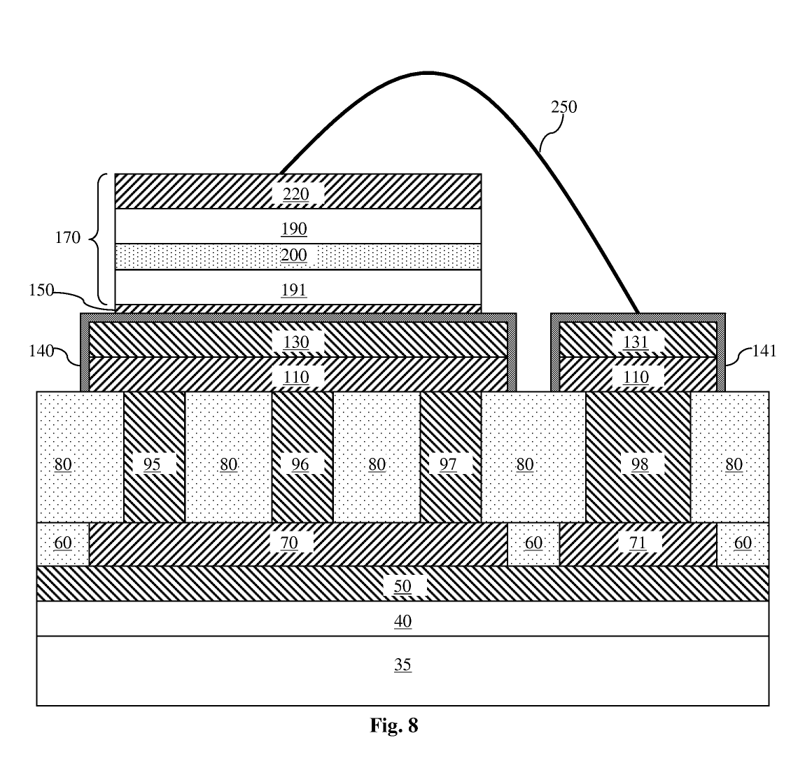

Referring now to FIG. 8, the substrate 180 (shown in FIG. 7) is removed. In one embodiment, the substrate 180 is removed by applying electromagnetic radiation to the photonic device 170. In other embodiments, the substrate 180 may be vaporized using a laser beam. Thereafter, the exposed surface of the doped layer 190 may undergo an optional roughening process to help propagate the light emitted by the photonic device 170 in an intended direction.

A conductive contact pad 220 is then formed on the doped layer 190. The conductive contact pad 220 has good thermal and electrical conductivity. The conductive contact pad 220 includes a transparent conductive material, such as indium tin oxide (ITO) or another suitable conductive material. The conductive pad 220 may be formed by a suitable technique, such as a PVD process. The size (for example, the lateral dimension) of the conductive contact pad 220 may vary depending on design needs. In the embodiment shown in FIG. 8, the entire area of the doped layer 190 is in direct physical contact with the conductive contact pad 220. In other embodiments, the area of contact may not be the entire area, but a substantial portion of the entire area. It is understood that the conductive contact pad 220 may be considered a portion of the thermally conductive structure 160.

Still referring to FIG. 8, a bonding wire 250 is bonded to the conductive contact pad 220 and the conductive contact pad 131 (through the barrier layer 141). In more detail, one end of the bonding wire 250 is bonded to the conductive pad 220, and the opposite end of the bonding wire 250 is bonded to the conductive contact pad 131. The bonding wire 250 electrically couples the photonic device 170 and the conductive contact pad 131. Thus, the bonding wire allows an electrical voltage to be applied to the photonic device 170 by applying the electrical voltage across the conductive contact pads 70 and 71, which are electrically coupled to the conductive contact pads 130 and 131, respectively.

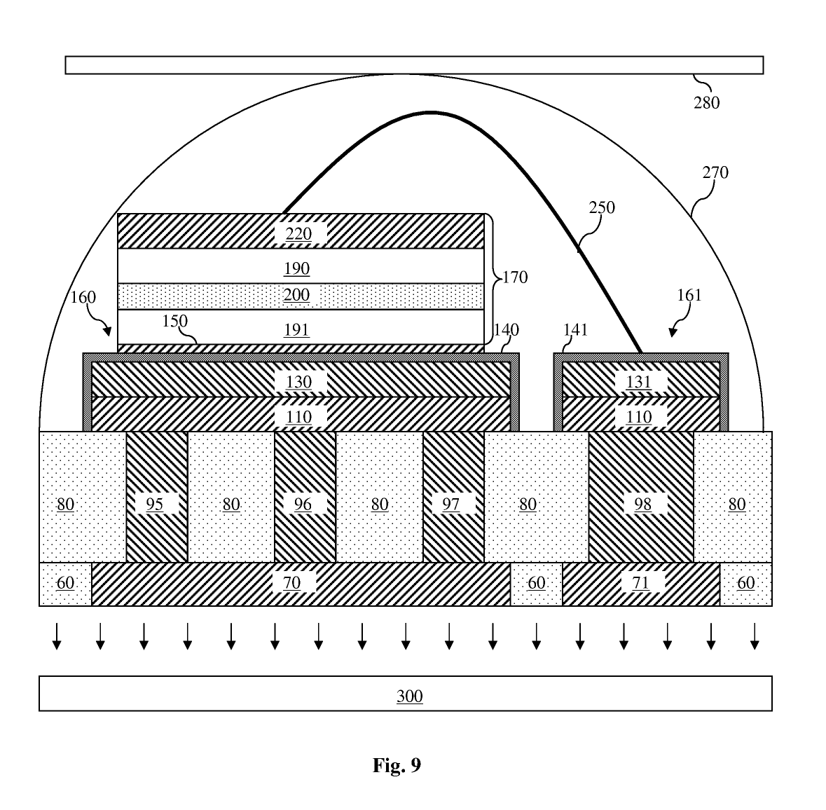

Referring now to FIG. 9, an encapsulant structure 270 is formed to mold the photonic device 170. The encapsulant structure 270 may include an organic material such as resin or plastic. If left exposed to air, the photonic device 170 may become corroded. Here, the encapsulant structure 270 provides sufficient sealing of the photonic device and thus minimizes the corrosion concerns. The encapsulant structure 270 may also be shaped as a lens, so that the light emitted by the photonic device 170 may be directed and focused in the intended propagation direction.

It is understood that FIGS. 2-9 illustrates portions of packaging for a single photonic device 170. Meanwhile, the method of packaging illustrated in FIGS. 2-9 has been performed to other photonic devices nearby. The packaging may be attached to a dicing frame 280. Next, the carrier substrate 35 is de-bonded from the packaging.

Afterwards, the photonic devices are separated from one another, for example by using a die saw, so that additional processes may be performed to complete the packaging of the photonic device 170. The sacrificial layer 40 (shown in FIGS. 2-8) is then removed. The conductive seed layer 50 (shown in FIGS. 2-8) is removed after the sacrificial layer 40 is removed. The bottom surfaces of the patterned insulating layer 60 and the conductive contact pads 70 and 71 are now exposed. A cleaning process may be optionally performed to clean these exposed surfaces. The photonic device 170 may then be detached from the dicing frame 280 and be packaged as a standalone photonic chip.

Thereafter, the packaged photonic chip may be attached to a printed circuit board (PCB) device 300. The PCB device 300 may have contact pads (not illustrated) that can be electrically coupled to the conductive conduct pads 70 and 71, so that a voltage can be applied to the photonic device 170 to control the operation of the photonic device 170.

The photonic device 170 may generate a large amount of heat during its operation. The dissipation of the heat generated has traditionally been a problem for photonic devices such as LED devices. For example, in some traditional LED devices, only a small fraction of a surface of the LED device may be in contact with a thermally conductive material that serves as a thermal dissipation conduit. The small contact area limits the rate at which the heat can be dissipated, thus resulting in inefficient thermal dissipation. As another example, some traditional LED devices include a sapphire substrate, which may trap the heat generated by the LED device inside the LED packaging. In some other traditional LED devices, deep and narrow openings may need to be etched into a substrate and then filled with a conductive material to form high aspect ratio vias. These vias are intended to dissipate heat generated by the LED device. However, they may be difficult and expensive to form due to their high aspect ratios.

In comparison, the LED packaging disclosed herein offer advantages compared to the traditional LED devices. It is understood, however, that other embodiments may offer different advantages, and that no particular advantage is required for all embodiments.

One advantage offered by the embodiments disclosed herein is better thermal dissipation. A substantial area of the bottom surface of the photonic device 170 is in direct physical contact with the thermally conductive structure 160, specifically in direct physical contact with the bond joint 150. This substantial area of direct physical contact leads to more efficient thermal dissipation compared to traditional LED devices. Also, the multiple interleaved conductive features 95-97 help reduce stress within the packaging while also serving as efficient thermal dissipation conduits. In this fashion, heat generated by the photonic device 170 may be quickly and effectively dissipated downwards through the thermally conductive structure 160.

In addition, the sapphire substrate 180 (shown in FIG. 7) has been removed from the photonic device 170 before it is packaged. As such, the photonic device 170 may have fast thermal dissipation in an upward direction as well. In other words, since the sapphire substrate 180 is no longer present, nothing would trap the heat inside the photonic device 170 from above. The conductive contact pad 220 has good thermal conductivity and helps dissipating heat upwards.

Further, the embodiments illustrated in FIGS. 2-9 involve a “build-up” (or stacking) approach. In other words, all the insulating materials (for example, the insulating layers 60 and 80) disclosed herein are formed by directly patterning them using a photolithography process. In comparison, traditional processes of forming LED packaging typically have to form trenches in an insulating material. Forming these trenches requires extra processes such as etching processes and thus increases fabrication costs.

Also, all the conductive materials (for example, the contact pads 70-71 and the conductive features 95-98) disclosed herein are formed by plating processes. In comparison, traditional LED packaging processes may need to fill those trenches with conductive materials. The conductive materials in the trenches may then need to be polished (for example, through a chemical-mechanical-polishing process) so that the conductive materials may be substantially co-planar with the trenches. Once again, the traditional processes involve using more fabrication processes. The traditional processes may also need a greater amount of conductive material, since the trenches may need to be over-filled before the polishing occurs. The additional processes and materials both increase fabrication costs. In comparison, the “build-up” approach of the embodiment illustrated in FIGS. 2-9 helps simplify fabrication processes and reduce fabrication costs. Moreover, in the embodiments disclosed herein, there is no need to form high aspect ratio vias.

It is understood that additional processes may be performed to complete the packaging of the photonic device 170. However, for the sake of simplicity, these processes are not illustrated or described herein.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An apparatus comprising a packaging for a light-emitting diode (LED) device, the packaging includes:
an insulating structure; and
first and second conductive structures that each extend through the insulating structure;
wherein:
a substantial area of a bottom surface of the LED device comes into contact with a top surface of the first conductive structure; and
a top surface of the LED device is bonded to the second conductive structure through a bonding wire.

2. The apparatus of claim 1, wherein the insulating structure includes a photoresist material.

3. The apparatus of claim 1, wherein the first conductive structure includes:
a top conductive pad that is disposed over the insulating structure and that comes into contact with the LED device;
a plurality of conductive columns disposed within the insulating structure and below the top conductive pad; and
a bottom conductive pad that is disposed within the insulating structure and below the conductive columns.

4. The apparatus of claim 3, wherein:
the insulating structure includes a plurality of insulating columns; and
the conductive columns are interleaved with the insulating columns.

5. An apparatus comprising a packaging structure for a photonic device, the packaging structure includes:
an insulating structure; and
a thermally conductive structure partially disposed in the insulating structure;
wherein a substantial portion of a surface of the photonic device is in direct contact with the thermally conductive structure.

6. The apparatus of claim 5, wherein the insulating structure includes a photo-sensitive material.

7. The apparatus of claim 5, wherein the surface of the photonic device is one of a top surface and a bottom surface, and wherein the entire portion of one of the top and bottom surfaces is in direct contact with the thermally conductive structure.

8. The apparatus of claim 5, wherein:
the packaging structure further includes a first conductive pad and a bonding wire;
the thermally conductive structure includes second and third conductive pads that are disposed over the insulating structure;
the first conductive pad is in direct contact with a first surface of the photonic device and is bonded to a first end of the bonding wire;
the second conductive pad is in direct contact with a second surface of the photonic device, the second surface being opposite from the first surface; and
the third conductive pad is bonded to a second end of the bonding wire, the first and second ends being opposite ends of the bonding wire.

9. The apparatus of claim 5, wherein the thermally conductive structure includes first and second conductive pads and a plurality of conductive features, the conductive features being disposed between the first and second conductive pads and interleaving with portions of the insulating structure.

10. The apparatus of claim 9, wherein the conductive features each have:
a first surface that is in direct contact with the first conductive pad; and
a second surface that is in direct contact with the second conductive pad; and wherein:
the first conductive pad and the conductive features are disposed in the insulating structure; and
the second conductive pad is disposed between the conductive features and the photonic device.

11. The apparatus of claim 9, wherein:
one of the portions of the insulating structure has a first lateral dimension value;
one of the conductive features has a second lateral dimension value, the first and second lateral dimension values being measured in a horizontal direction; and
a ratio between the first and second lateral dimension values is in a range from approximately 0.5 to approximately 5.

12. A method of packaging a light-emitting diode (LED) device, comprising:
forming an insulating structure;
forming a thermally conductive structure partially in the insulating structure;
providing the LED device, the LED device having a top surface and a bottom surface; and
bonding the LED device to the thermally conductive structure, the bonding being carried out in a manner so that a substantial portion of one of the top and bottom surfaces of the LED device is in direct contact with the thermally conductive structure.

13. The method of claim 12, wherein the forming the insulating structure is carried out in a manner so that the insulating structure includes a photo-sensitive material.

14. The method of claim 12, wherein the bonding the LED device is carried out in a manner so that an entire portion of one of the top and bottom surfaces of the LED device is in direct contact with the thermally conductive structure.

15. The method of claim 12, wherein:
the forming the thermally conductive structure is carried out in a manner so that the thermally conductive structure includes:
a first conductive pad that is disposed over the LED device; and
second and third conductive pads that are disposed over the insulating structure;
the bonding the LED device is carried out in a manner so that:
the first conductive pad is in direct contact with the top surface of the LED device; and
the second conductive pad is in direct contact with the bottom surface of the LED device;
and further including bonding the first and third conductive pads to opposite ends of a bonding wire.

16. The method of claim 12, wherein the forming the thermally conductive structure includes:
forming a first conductive pad in the insulating structure;
forming a plurality of conductive features over the first conductive pad, the conductive features interleaving with portions of the insulating structure; and
forming a second conductive pad over the conductive features and over the insulating structure.

17. The method of claim 16, wherein the bonding the LED device is carried out so that the surface of the LED device is in direct contact with the second conductive pad.

18. The method of claim 16, wherein:
the forming the insulating structure includes forming the portions of the insulating structure by forming a photoresist layer over the first conductive pad and patterning the photoresist layer using a photolithography process, the patterned photoresist layer being the portions of the insulating structure, the portions of the insulating structure having a plurality of openings; and
the forming the conductive features includes forming a conductive material in the openings using a plating process.

19. The method of claim 18, wherein the forming the portions of the insulating structure is carried out in a manner so that:
one of the portions of the insulating structure has a first lateral dimension value;
one of the conductive features has a second lateral dimension value, the first and second lateral dimension values being measured in the same direction; and
a ratio between the first and second lateral dimension values is in a range from approximately 0.5 to approximately 5.

20. The method of claim 12, wherein the forming the insulating structure is carried out so that the insulating structure is formed over a carrier substrate, and further including:
molding the LED device;
attaching the molded LED device to a dicing frame; and
removing the carrier substrate.
